(19) United States
(12) Patent Application Publication
(10) Pub. No.: US 2023/0116500 A1
(43) Pub. Date: Apr. 13, 2023

(54) SIGNAL COMBINING AND DISTRIBUTION NETWORK APPARATUS INCLUDING MULTI-ARRAY CIRCUITS

(71) Applicant: ELECTRONICS AND TELECOMMUNICATIONS RESEARCH INSTITUTE, Daejeon (KR)

(72) Inventors: Sooyeon KIM, Daejeon (KR); Seung Hwan KIM, Daejeon (KR); Seung-Hyun CHO, Daejeon (KR)

(21) Appl. No.: 17/547,843

(22) Filed: Dec. 10, 2021

(30) Foreign Application Priority Data
Oct. 12, 2021 (KR) 10-2021-0135155

(51) Int. Cl. H03B 5/02

(52) U.S. Cl. CPC H03B 5/02

(57) ABSTRACT

Disclosed is a signal combining and distribution network apparatus including multi-array circuits. The signal combining and distribution network apparatus includes multi-array circuits each including a plurality of oscillators, and 2-terminal networks a arranged between the oscillators and including a slow wave structure or a coupled line filter, and 2-terminal networks c arranged between the multi-array circuits and including a slow wave structure or a coupled line filter.

### CROSS-REFERENCE TO RELATED APPLICATION

This application claims the benefit of Korean Patent Application No. 10-2021-0135155 filed on Oct. 12, 2021, in the Korean Intellectual Property Office, the entire disclosure of which is incorporated herein by reference for all purposes.

### BACKGROUND

### 1. Field of the Invention

One or more example embodiments relate to a signal combining and distribution network apparatus, and more particularly, to a signal combining and distribution network apparatus including multi-array circuits.

### 2. Description of Related Art

When an operating frequency is high, such as a millimeter band or sub-millimeter band, low gain and output of an active device and a loss of a passive device may hinder high power generation. Thus, it is advantageous to combine outputs of multi-arrayed circuits to obtain high power. In addition, a reduced size of the passive device may lead to a reduction in the size of a circuit in such a high frequency band, which may act as an advantage in multi-array configuration by integrating more circuits in the same area than in a low frequency band. Typical circuits that require high power generation include oscillators, amplifiers, and the like.

When output signals of multiple oscillators are combined, signals with the same frequency and phase need to be combined to effectively increase output power, which requires coupling between multi-arrayed oscillators.

Conventional signal combining and distribution network apparatuses include a structure in which a reference signal is injected into each oscillator through a distribution network, or a structure in which adjacent oscillators have fixed frequency and phase through local coupling, but designing such coupling structures is very difficult.

Therefore, there is a demand for a signal combining and distribution network apparatus with low design difficulty.

### SUMMARY

Example embodiments provide a multi-array circuit that may need a small area and be easily expanded in a millimeter and sub-millimeter band.

Example embodiments provide a signal combining and distribution network apparatus that has low design difficulty as including multi-array circuits that may need a small area and be easily expanded in a millimeter and sub-millimeter band.

According to an aspect, there is provided a multi-array circuit including a plurality of oscillators, and 2-terminal networks a arranged between the oscillators and including a slow wave structure or a coupled line filter.

The 2-terminal networks a may include slow wave structures or a plurality of coupled line filters having different structures.

The 2-terminal networks a may include slow wave structures or a plurality of coupled line filters having a same structure.

The 2-terminal networks a may have an electrical length that is determined according to a phase difference between oscillators connected between the 2-terminal networks a.

The multi-array circuit may further include 2-terminal networks b arranged between the 2-terminal networks a and the oscillators and including a slow wave structure or a coupled line filter.

According to an aspect, there is provided a signal combining and distribution network apparatus including multi-array circuits each including a plurality of oscillators, and 2-terminal networks a arranged between the oscillators and including a slow wave structure or a coupled line filter, and 2-terminal networks c arranged between the multi-array circuits and including a slow wave structure or a coupled line filter.

The 2-terminal networks a and the 2-terminal networks c may include slow wave structures or a plurality of coupled line filters having different structures.

The 2-terminal networks a and the 2-terminal networks c may include slow wave structures or a plurality of coupled line filters having a same structure.

The multi-array circuits may further include 2-terminal networks b arranged between the 2-terminal networks a and the oscillators and including a slow wave structure or a coupled line filter.

The 2-terminal networks a and the 2-terminal networks c may have an electrical length that is determined according to a phase difference between oscillators connected between the 2-terminal networks a and the 2-terminal networks c.

Additional aspects of example embodiments will be set forth in part in the description which follows and, in part, will be apparent from the description, or may be learned by practice of the disclosure.

According to example embodiments, it is possible to provide a multi-array circuit that may need a small area and be easily expanded in a millimeter and sub-millimeter band.

According to example embodiments, it is possible to provide a signal combining and distribution network apparatus that has low design difficulty as including multi-array circuits that may need a small area and be easily expanded in a millimeter and sub-millimeter band.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a multi-array circuit according to an example embodiment;

FIG. 2 illustrates a structure of a 2-terminal network of a multi-array circuit according to an example embodiment;

FIG. 3 illustrates an example of a coupled line filter included in a line structure according to an example embodiment;

FIG. 4 illustrates a signal combining and distribution network apparatus including multi-array circuits according to an example embodiment;

FIG. 5 illustrates a structure of a 2-terminal network included in FIG. 4; and

FIG. 6 illustrates a signal distribution network apparatus including multi-array circuits according to an example embodiment.

### DETAILED DESCRIPTION

Hereinafter, example embodiments will be described in detail with reference to the accompanying drawings. However, various alterations and modifications may be made to the example embodiments. Here, the example embodiments are not construed as limited to the disclosure. The example embodiments should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

When describing the example embodiments with reference to the accompanying drawings, like reference numerals refer to like constituent elements and a repeated description related thereto will be omitted. In the description of example embodiments, detailed description of well-known related structures or functions will be omitted when it is deemed that such description will cause ambiguous interpretation of the present disclosure.

Hereinafter, example embodiments will be described in detail with reference to the accompanying drawings.

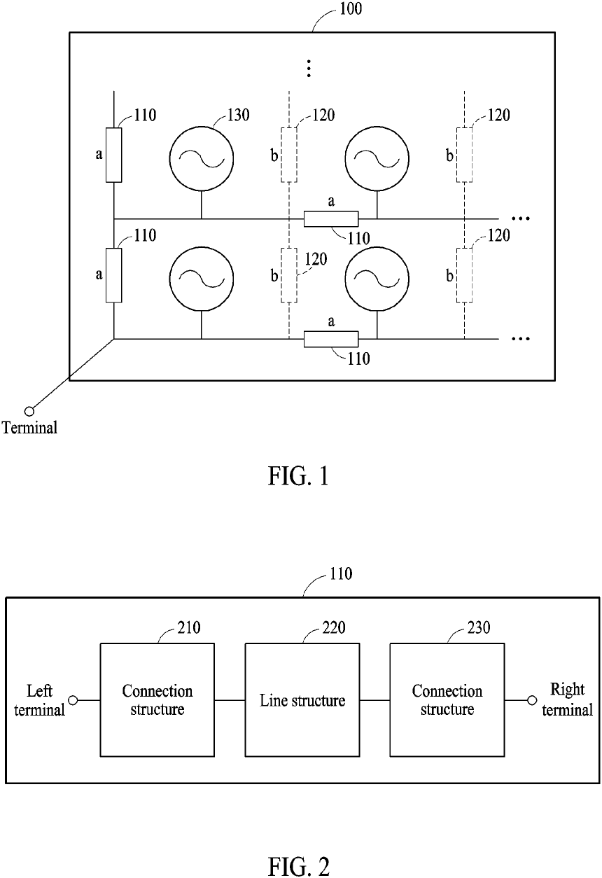

FIG. 1 illustrates a multi-array circuit according to an example embodiment.

Referring to FIG. 1, a multi-array circuit 100 may include 2-terminal networks a 110, 2-terminal networks b 120, and a plurality of oscillators 130.

The 2-terminal networks a 110 may each be arranged between oscillators 130, and include a slow wave structure or a coupled line filter.

In addition, the 2-terminal networks b 120 may be arranged between the 2-terminal networks a 110 and the oscillators 130, and include a slow wave structure or a coupled line filter.

The 2-terminal networks a 110 and the 2-terminal networks b 120 may include only a single slow wave structure or a single coupled line filter. Alternatively, the 2-terminal networks a 110 and the 2-terminal networks b 120 may include a plurality of slow wave structures or a plurality of coupled line filters. In addition, the slow wave structures or the coupled line filters may include open stubs or short stubs.

At this time, the 2-terminal networks a 110 and the 2-terminal networks b 120 may have an electrical length of 2πn. Here, n is an integer.

An oscillator 130 may be a single oscillator, or a differential oscillator, or an oscillator that generates a harmonic frequency signal.

In addition, the multi-array circuit 100 may be manufactured in a structure in which the plurality of oscillators 130 are coupled adjacent to each other. At this time, the 2-terminal networks b 120 arranged between the 2-terminal networks a 110 and the oscillators 130 may be opened.

FIG. 2 illustrates a structure of a 2-terminal network of a multi-array circuit according to an example embodiment.

Referring to FIG. 2, a 2-terminal network a 110 may include a left terminal, a connection structure 210, a line structure 220, a connection structure 230, and a right terminal. In addition, although FIG. 2 only illustrates the structure of a 2-terminal network a 110, a 2-terminal network b 120 may also be manufactured in the same structure as the 2-terminal network a 110. At this time, the line structure 220 of the 2-terminal network a 110 may include a plurality of slow wave structures or a plurality of coupled line filters having different structures. Alternatively, the line structure 220 may include a plurality of slow wave structures or a plurality of coupled line filters having the same structure. Additionally, the line structure 220 may be manufactured with a single slow wave structure or a single coupled line filter.

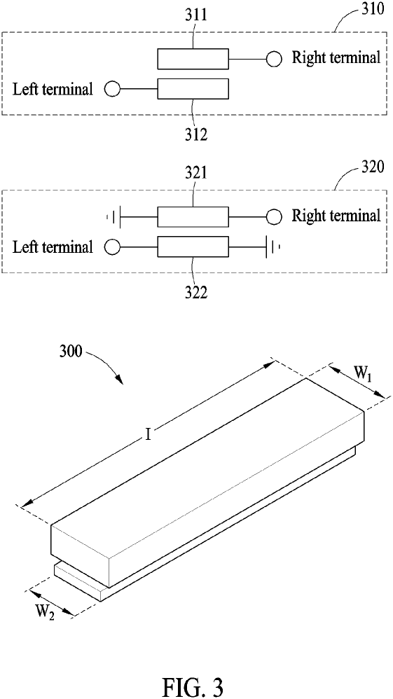

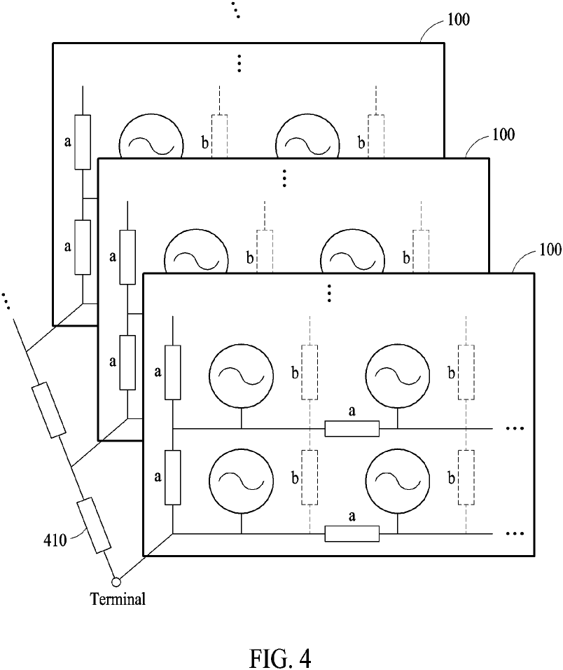

The structure of the coupled line filter of the line structure 220 will be described in detail below with reference to FIG. 3. In addition, the slow wave structure of the line structure 220 will be described in detail with reference to FIG. 4.

The 2-terminal network a 110 may have an electrical length that is determined according to a phase difference between oscillators 130 connected between 2-terminal networks a 110. For example, when the phase difference between the oscillators is θ, the sum of the electrical length of the 2-terminal network a 110 and θ may be 2πn.

FIG. 3 illustrates an example of a coupled line filter included in a line structure according to an example embodiment.

A coupled line filter of the line structure 220 may be in a structure in which two of four terminals of a coupled line in which at least two metal structures are arranged on the same plane or vertically are used as input and output terminals and the other two terminals are open or grounded.

For example, a coupled line filter 310 of the line structure 220 may include a metal structure 311 and a metal structure 312, and be in a structure in which a right terminal of the metal structure 311 and a left terminal of the metal structure 312 are used as input and output terminals and a left terminal of the metal structure 311 and a right terminal of the metal structure 312 are open.

Further, a coupled line filter 320 of the line structure 220 may include a metal structure 321 and a metal structure 322, and be in a structure in which a right terminal of the metal structure 321 and a left terminal of the metal structure 322 are used as input and output terminals and a left terminal of the metal structure 321 and a right terminal of the metal structure 322 are grounded.

The metal structure 311, the metal structure 312, the metal structure 321, and the metal structure 322 may be manufactured in the same format as a metal structure 300 shown in FIG. 3.

In addition, the performance of the coupled line filter 310 and the coupled line filter 320 may be as shown in Table 1.

TABLE 1

| | | | | | |
|---|---|---|---|---|---|
| | 75-Ω transmission line | Wilkinson power divider | Example 1 of coupled line filter | Example 2 of coupled line filter | Slow wave structure |
| w (µm) | 6 | 24 | 10 | 10 | 8 |
| l (µm) | 180 | 180 or higher | 45 | 67.5 | 128 |
| Phase(S21) (°) | -90 | - | 0.07 | -180 | -90 |
| 180° structure area (µm²) | 2160 | - | - | 675 | 1024 |
| 360° structure area (µm²) | 4320 | - | 450 | 1350 | 2048 |
| Area (µm²) | - | 4320 or higher | - | - | - |

The electrical length may be implemented even with a line shorter than a typical transmission line.

FIG. 4 illustrates a signal combining and distribution network apparatus including multi-array circuits according to an example embodiment.

Referring to FIG. 4, a signal combining and distribution network apparatus may include a plurality of multi-array circuits 100 and 2-terminal networks c 410.

A multi-array circuit 100 may include a plurality of oscillators 130, 2-terminal networks a 110 arranged between oscillators 130 including a slow wave structure or a coupled line filter, and 2-terminal networks b 120 arranged between the 2-terminal networks a 110 and the oscillators 130 and including a slow wave structure or a coupled line filter.

A 2-terminal network c 410 may be arranged between multi-array circuits 100, and include a slow wave structure or a coupled line filter. In addition, the 2-terminal network c 410 may have an electrical length of 2πn and be shorted when the multi-array circuits 100 are arranged very adjacent to each other. Thus, if multi-array circuits 100 are arranged at an interval less than or equal to a threshold interval, the multi-array circuit 100 may not include a 2-terminal network c 410.

In addition, when the 2-terminal network a 110, the 2-terminal network b 120, and the 2-terminal network c 410 are manufactured in an electrical length of 2πn + θ, a phase difference between two oscillators connected to the 2-terminal network a 110, the 2-terminal network b 120, and the 2-terminal network c 410 may be adjusted to 2πm - θ in the signal combining and distribution network apparatus.

As shown in FIG. 4, by arranging 2-terminal networks having a slow wave structure or a coupled line filter between oscillators, the signal combining and distribution network apparatus may require a small area and have a high expandability, thereby distributing/combining inputs and outputs of more circuits and systems.

A network apparatus using local coupling may need to simulate a plurality of oscillators at the same time by including a structure for utilizing coupling in designing oscillators. However, as a basic unit of a network design become more complex, the difficulty of the design increases. In addition, a method of distributing an injection signal had a limitation that the network may not be expanded infinitely due to a loss of the injection signal.

Since it is possible to separately design individual oscillators, 2-terminal networks 110, 2-terminal networks 120, and 2-terminal networks 410, the signal combining and distribution network apparatus may have a simple basic unit of the network design and thus, have a lower design difficulty than the network apparatus using local coupling.

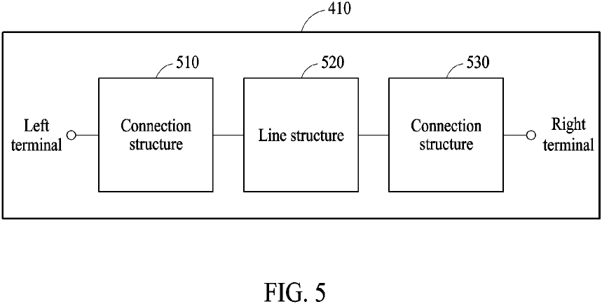

FIG. 5 illustrates a structure of a 2-terminal network included in FIG. 4.

Referring to FIG. 5, the 2-terminal network c 410 may include a left terminal, a connection structure 510, a wave structure 520, a connection structure 530, and a right terminal.

At this time, the wave structure 520 of the 2-terminal network c 410 may include a plurality of slow wave structures or a plurality of coupled line filters having different structures. Alternatively, the wave structure 520 may include a plurality of slow wave structures or a plurality of coupled line filters having the same structure. Additionally, the wave structure 520 may be manufactured with one slow wave structure or one coupled line filter.

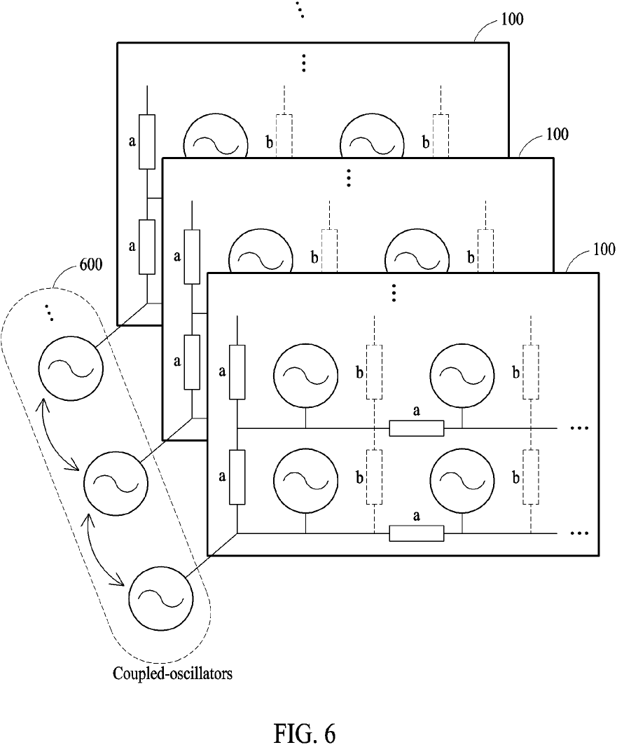

FIG. 6 illustrates a signal distribution network apparatus including multi-array circuits according to an example embodiment.

Referring to FIG. 6, a signal distribution network apparatus may be manufactured by coupling 600 a plurality of multi-array circuits 100 according to a local coupling method. In addition, since reference signals applied respectively to oscillators have the same phase in the signal distribution network apparatus, the frequencies and phases of the oscillators 130 of the multi-array circuits 100 may be the same as well.

According to example embodiments, it is possible to provide a multi-array circuit that may need a small area and be easily expanded in a millimeter and sub-millimeter band.

According to example embodiments, it is possible to provide a signal combining and distribution network apparatus that has low design difficulty as including multi-array circuits that may need a small area and be easily expanded in a millimeter and sub-millimeter band.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

Meanwhile, the combining and distribution network apparatus according to the present disclosure may be written in a computer-executable program and may be implemented as various recording media such as magnetic storage media, optical reading media, or digital storage media.

Various techniques described herein may be implemented in digital electronic circuitry, computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal, for processing by, or to control an operation of, a data processing apparatus, e.g., a programmable processor, a computer, or multiple computers. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory, or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as compact disk read only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include both computer storage media and transmission media.

Although the present specification includes details of a plurality of specific example embodiments, the details should not be construed as limiting any invention or a scope that can be claimed, but rather should be construed as being descriptions of features that may be peculiar to specific example embodiments of specific inventions. Specific features described in the present specification in the context of individual example embodiments may be combined and implemented in a single example embodiment. On the contrary, various features described in the context of a single embodiment may be implemented in a plurality of example embodiments individually or in any appropriate sub-combination. Furthermore, although features may operate in a specific combination and may be initially depicted as being claimed, one or more features of a claimed combination may be excluded from the combination in some cases, and the claimed combination may be changed into a sub-combination or a modification of the sub-combination.

Likewise, although operations are depicted in a specific order in the drawings, it should not be understood that the operations must be performed in the depicted specific order or sequential order or all the shown operations must be performed in order to obtain a preferred result. In specific cases, multitasking and parallel processing may be advantageous. In a specific case, multitasking and parallel processing may be advantageous. In addition, it should not be understood that the separation of various device components of the aforementioned example embodiments is required for all the example embodiments, and it should be understood that the aforementioned program components and apparatuses may be integrated into a single software product or packaged into multiple software products.

The example embodiments disclosed in the present specification and the drawings are intended merely to present specific examples in order to aid in understanding of the present disclosure, but are not intended to limit the scope of the present disclosure. It will be apparent to those skilled in the art that various modifications based on the technical spirit of the present disclosure, as well as the disclosed example embodiments, can be made.

What is claimed is:

1. A multi-array circuit comprising:
a plurality of oscillators; and
2-terminal networks a arranged between the oscillators and comprising a slow wave structure or a coupled line filter.

2. The multi-array circuit of claim 1, wherein the 2-terminal networks a comprise slow wave structures or a plurality of coupled line filters having different structures.

3. The multi-array circuit of claim 1, wherein the 2-terminal networks a comprise slow wave structures or a plurality of coupled line filters having a same structure.

4. The multi-array circuit of claim 1, wherein the 2-terminal networks a have an electrical length that is determined according to a phase difference between oscillators connected between the 2-terminal networks a.

5. The multi-array circuit of claim 1, further comprising:
2-terminal networks b arranged between the 2-terminal networks a and the oscillators and including a slow wave structure or a coupled line filter.

6. A signal combining and distribution network apparatus comprising:
multi-array circuits each comprising a plurality of oscillators, and 2-terminal networks a arranged between the oscillators and comprising a slow wave structure or a coupled line filter; and
2-terminal networks c arranged between the multi-array circuits and comprising a slow wave structure or a coupled line filter.

7. The signal combining and distribution network apparatus of claim 6, wherein the 2-terminal networks a and the 2-terminal networks c comprise slow wave structures or a plurality of coupled line filters having different structures.

8. The signal combining and distribution network apparatus of claim 6, wherein the 2-terminal networks a and the 2-terminal networks c comprise slow wave structures or a plurality of coupled line filters having a same structure.

9. The signal combining and distribution network apparatus of claim 6, wherein the multi-array circuits further comprise 2-terminal networks b arranged between the 2-terminal networks a and the oscillators and comprising a slow wave structure or a coupled line filter.

10. The signal combining and distribution network apparatus of claim 6, wherein the 2-terminal networks a and the 2-terminal networks c have an electrical length that is determined according to a phase difference between oscillators connected between the 2-terminal networks a and the 2-terminal networks c.
